(19) United States
(12) Patent Application Publication
(10) Pub. No.: US 2013/0221397 A1
(43) Pub. Date: Aug. 29, 2013

(54) LIGHT EMITTING ELEMENT STRUCTURE AND CIRCUIT OF THE SAME

(71) Applicants: Hieng-Hsiung Huang, Hsinchu City (TW); Chun-Ming Huang, Taichung City (TW); Wen-Chun Wang, Taichung City (TW); David Stevenson, Dexter, MI (US); Cheng-Yi Cheng, Changhua County (TW); Hsi-Rong Han, Taichung City (TW)

(72) Inventors: Hieng-Hsiung Huang, Hsinchu City (TW); Chun-Ming Huang, Taichung City (TW); Wen-Chun Wang, Taichung City (TW); David Stevenson, Dexter, MI (US); Cheng-Yi Cheng, Changhua County (TW); Hsi-Rong Han, Taichung City (TW)

(73) Assignee: WINTEK CORPORATION, Taichung City (TW)

(21) Appl. No.: 13/773,656

(22) Filed: Feb. 22, 2013

(30) Foreign Application Priority Data
Feb. 24, 2012 (TW) 101106333

(51) Int. Cl. H01L 33/36

(52) U.S. Cl. CPC H01L 33/36
USPC 257/99

(57) ABSTRACT

A light emitting element structure and a circuit thereof are provided. The light emitting element circuit includes a driving unit and a light emitting element. The driving unit is used for generating a driving current at a light emission period. The light emitting element includes a current transferring unit and a light emitting unit. The current transferring unit is connected with the driving unit to transfer the driving current and generate a light emitting current at the light emission period. The light emitting unit is connected with the current transferring unit and emits light in response to the light emitting current. The light emitting unit is connected with the current transferring unit and emits light in response to the light emitting current.

### CROSS-REFERENCE TO RELATED APPLICATION

This application claims the priority benefit of Taiwan application serial no. 101106333, filed on Feb. 24, 2012. The entirety of the above-mentioned patent application is hereby incorporated by reference herein and made a part of this specification.

### BACKGROUND OF THE DISCLOSURE

1. Field of the Disclosure

The invention is directed to a light emitting element and a circuit of the same. In particular, the invention is directed to a structure of an electro-luminescence element and a circuit of the same.

2. Description of Related Art

A light emitting diode element is a semiconductor device capable of efficiently converting electrical energy into optical energy, which is wildly applied to indication lights, display panels and optical reading/writing heads. The light emitting diode element has features such as free-viewing angles, simple processing, low production cost, fast response, wide operation temperature range and full color displaying meet the demands of modern display devices in the multimedia field. So, in recent years, the light emitting diode element becomes enthusiastically researched and developed.

The light emitting diode element utilizes a number of transistors and at least a capacitor to implement an active driving manner. Said transistors may at least include a switching transistor and a driving transistor. When the switching transistor is enabled by a scan line signal, a voltage on a data line is transmitted to a gate of the driving transistor for driving thereof, and the capacitor is charged by the voltage at the same time. In addition, when the voltage on the data line is received by the driving transistor, the driving transistor is enabled so as to drive the current flowing through a light emitting layer. When the driving current is sufficient, the light emitting layer emits light. That is, the driving transistor needs to be driven by such driving current for a long time, which may result in the variance of the element properties causing insufficient reliability.

### SUMMARY OF THE DISCLOSURE

The invention provides a light emitting element structure. The light emitting element structure is driven by a current lower than that for driving a light emitting layer so as to maintain properties of driving elements.

The invention also provides a circuit of a light emitting element structure. The light emitting element adopts a light emitting unit driven by a small current so as to maintain the reliability of the circuit elements.

The invention provides a light emitting element structure, which is disposed on a substrate. The light emitting elements include a driving circuit layer, a first electrode layer, a second electrode layer, an active layer, a first carrier transporting layer, a second carrier transporting layer and a transmission electrode layer. The driving circuit layer is disposed on the substrate. The first electrode layer and the second electrode layer are connected with the driving circuit layer. The active layer is located between the first electrode layer and the second electrode layer. The first carrier transporting layer is located between the first electrode layer and the active layer. The first carrier transporting layer includes two first carrier transporting sub-layers which are stacked with each other. The second carrier transporting layer is located between the second electrode layer and the active layer. The transmission electrode layer is connected with the driving circuit layer and located between the two first carrier transporting sub-layers. A first current outputted by the driving circuit layer is inputted into a stack of the two first carrier transporting sub-layers and the transmission electrode layer via the first electrode layer and the transmission electrode layer so as to generate a second current flowing through the active layer. The second current is larger than the first current.

In an embodiment of the invention, the first carrier transporting layer and the second carrier transporting layer are respectively used for transporting different carriers. The carriers include electrons and electron-holes.

In an embodiment of the invention, a material of the transmission electrode layer includes a metal, a metal oxide, a graphite carbon or a carbon nano-tube.

In an embodiment of the present invention, the transmission electrode layer has a plurality of holes with sub-micron diameter.

In an embodiment of the invention, the transmission electrode layer is a transparent transmission electrode layer.

In an embodiment of the invention, the first electrode layer is located at a side of the active layer that is adjacent to the substrate, and the second electrode layer is located at another side of the active layer that is away from the substrate.

In an embodiment of the invention, the first electrode layer is located at a side of the active layer that is away from the substrate, and the second electrode layer is located at another side of the active layer that is adjacent to the substrate.

In an embodiment of the invention, the light emitting element structure further includes a first carrier injecting layer which is located between the first carrier transporting layer and the first electrode layer.

In an embodiment of the invention, the light emitting element structure further includes a second carrier injecting layer which is located between the second carrier transporting layer and the second electrode layer.

In an embodiment of the invention, a material of the active layer is a light emitting material.

In an embodiment of the present invention, at least one of the first electrode layer and the second electrode layer is a transparent transmission electrode layer.

The invention further provides a light emitting element circuit which includes a driving unit and a light emitting element. The driving unit is used for generating a driving current at a light emission period. The light emitting element includes a current transferring unit and a light emitting unit. The current transferring unit is connected with the driving unit so as to receive and transfer the driving current at the light emission period to generate a light emitting current. The light emitting unit is connected with the current transferring unit. At the light emission period, the light emitting unit emits light in response to the light emitting current.

In an embodiment of the present invention, the light emitting current flowing through the light emitting unit is functioned by the current transferring unit so that a value of the light emitting current is larger than that of the driving current.

In an embodiment of the invention, the light emitting unit includes a stack consisting in turn of a first electrode layer, two first carrier transporting sub-layers, a light emitting layer, a second carrier transporting layer and a second electrode layer. In addition, the current transferring unit consists of the two first carrier transporting sub-layers and a transmission electrode layer located between the two first carrier transporting layers. The transmission electrode layer and the two first carrier transporting sub-layers of the current transferring unit are respectively connected with the driving unit, a system potential and a reference potential. The light emitting unit is connected between the current transferring unit and the system potential. Alternatively, the light emitting unit is connected between the current transferring unit and the reference potential.

In an embodiment of the invention, the driving unit consists of at least one transistor and at least one capacitor.

In an embodiment of the invention, the current transferring unit and the driving unit are coupled to a same system potential.

In an embodiment of the invention, the current transferring unit is coupled to a system potential, and the driving unit is coupled to another system potential.

In view of the foregoing, an electrode layer is inserted into one of the carrier transporting layers of the light emitting element structure according to the invention. At this time, an inputted current is transferred by the stack of the electrode layer and the carrier transporting layers so as to drive the light emitting layer of the light emitting element structure. Accordingly, an external current needed by the light emitting element structure can be reduced so as to maintain properties and the reliability of each element in the circuit.

In order to make the aforementioned properties and advantages of the invention more comprehensible, embodiments accompanied with figures are described in detail below.

### BRIEF DESCRIPTION OF THE DRAWINGS

The accompanying drawings constituting a part of this specification are incorporated herein to provide a further understanding of the invention. Here, the drawings illustrate embodiments of the invention and, together with the description, serve to explain the principles of the invention.

FIG. 1A is a schematic cross-sectional view of a light emitting element structure according to an embodiment of the invention.

FIG. 1B is a schematic cross-sectional view of a light emitting element structure according to another embodiment of the invention.

FIG. 2A is a schematic view of a light emitting element circuit 1 according to an exemplary embodiment of the invention.

FIG. 2B is a schematic view of a light emitting element circuit 1′ according to an exemplary embodiment of the invention.

FIG. 3A is a schematic view illustrating the light emitting element circuit depicted in FIG. 2A implemented by another method.

FIG. 3B is a schematic view illustrating the light emitting element circuit depicted in FIG. 2B implemented by another method.

FIG. 4A is a schematic view illustrating the light emitting element circuit depicted in FIG. 2A implemented by further another method.

FIG. 4B is a schematic view illustrating the light emitting element circuit depicted in FIG. 2B implemented by still another method.

FIG. 5 is a schematic view illustrating the light emitting element circuit depicted in FIG. 2B implemented by further still another method.

### DETAILED DESCRIPTION OF THE EMBODIMENTS

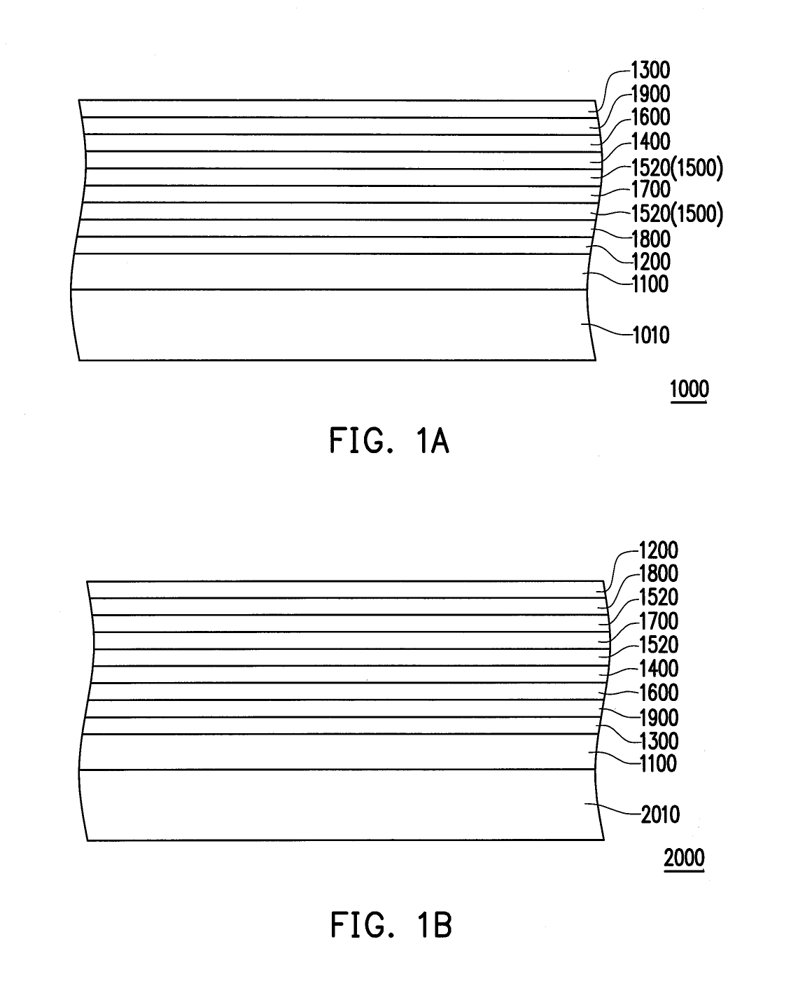

FIG. 1A is a schematic cross-sectional view of a light emitting element structure according to an embodiment of the invention. Referring to FIG. 1A, the light emitting element structure 1000 is disposed on a substrate 1010. The light emitting element structure 1000 includes a driving circuit layer 1100, a first electrode layer 1200, a second electrode layer 1300, an active layer 1400, a first carrier transporting layer 1500, a second carrier transporting layer 1600, a transmission electrode layer 1700, a first carrier injecting layer 1800 and a second carrier injecting layer 1900.

In particular, according to the present embodiment, the aforementioned components are stacked in turn by the driving circuit layer 1100, the first electrode layer 1200, the first carrier injecting layer 1800, the first carrier transporting layer 1500, the transmission electrode layer 1700, the active layer 1400, the second carrier transporting layer 1600, the second carrier injecting layer 1900, and the second electrode layer 1300. That is, the first electrode layer 1200 is located at a side of the active layer 1400 that is adjacent to the substrate 1010, and the second electrode layer 1300 is located at another side of the active layer 1400 that is away from substrate 1010. However, in another embodiment, the structure of such stack may be disposed reversely, and the invention is not limited to this.

The driving circuit layer 1100 is disposed on the substrate 1010. The driving circuit layer 1100 may be connected with an external circuit so that a current and/or a voltage required for driving the active layer 1400 is inputted to the active layer 100 by the function of the driving circuit layer 1100. Therefore, the active layer 1400 generates a reaction in response, for example, emitting light. Though the driving circuit layer 1100 in the present embodiment is schematically shown in a layer, the driving circuit layer 1100 may actually consist of at least one transistor and at least one capacitor. Besides the transistor and the capacitor, the driving circuit layer 1100 may further include other circuit elements according to other embodiments. In particular, the embodiment does not intend to limit the elements included in the driving circuit layer 1100. Circuit layouts in this art that are capable of inputting the current and/or voltage from the external to the active layer 140 may be applied to the driving circuit layer 1100.

The first electrode layer 1200 and the second electrode layer 130 are electrode layers used for being connected with the driving circuit layer 1100 and provided with conductivities. In addition, the active layer 1400 is located between the first electrode layer 1200 and the second electrode layer 1300. In the present embodiment, the active layer 1400 is, for example, a light emitting layer, which emits light when being driven by electricity. Thus, to emit out a light from the active layer 1400, at least one of the first electrode layer 1200 and the second electrode layer 1300 is a transparent electrode layer. In other words, at least one of the first electrode layer 1200 and the second electrode layer 1300 has not only conductivities but also light transparence and thus, may be made by a transparent conductive material, such as indium-tin-oxide (ITO) or indium-zinc-oxide (IZO), which the invention is not limited thereto.

The first carrier transporting layer 1500 is located between the first electrode layer 1200 and the active layer 1400. The second carrier transporting layer 1600 is located between the second electrode layer 1300 and the active layer 1400. The first carrier transporting layer 1500 and the second carrier transporting layer 1600 are respectively used for transporting different carriers. Here, the carriers as described include electrons and electron-holes. The first carrier transporting layer 1500 and the second carrier transporting layer 1600 transport the carriers inputted by the first electrode layer 1200 and the second electrode layer 1300 to the active layer 1400. At this time, the two types of carriers, the electrons and the electron-holes, may be recombined in the active layer 1400 so as to emit light, which is the emission mechanism of the light emitting element structure 1000 according to the present embodiment. Accordingly, as for the emission mechanism, the light emitting element structure 1000 of the present embodiment may be considered as a type of light emitting diode (LED).

In other words, with the selection of materials, the first carrier transporting layer 1500 and the second carrier transporting layer 1600 according to the present embodiment may be respectively provided with different work functions for transporting different types of carriers. If the first carrier transporting layer 1500 is an electron transporting layer, the second carrier transporting layer 1600 is an electron-hole transporting layer. Here, the first electrode layer 1200 and the second electrode layer 130 may be respectively considered as a cathode electrode layer and an anode electrode layer. On the other hand, if the first carrier transporting layer 1500 is an electron-hole transporting layer, the second carrier transporting layer 1600 is an electron transporting layer. At this time, the first electrode layer 1200 and the second electrode layer 130 may be respectively considered as the anode electrode layer and the cathode electrode layer.

In addition, the light emitting element structure 1000 may selectively be disposed with the first carrier injecting layer 1800 and the second carrier injecting layer 1900. The first carrier injecting layer 1800 is located between the first carrier transporting layer 1500 and the first electrode layer 1200. The second carrier injecting layer 1900 is located between the second carrier transporting layer 1600 and the second electrode layer 1300. The carrier injecting layer under discussion may provide an appropriate mechanism to inject the carriers (including electrons or electron-holes) into a carrier transportation, and thus, the work functions of the first carrier injecting layer 1800 and the second carrier injecting layer 1900 may be determined by the first carrier transporting layer 1500 and the second carrier transporting layer 1600. When the first carrier transporting layer 1500 is the electron transporting layer, and the second carrier transporting layer 1600 is the electron-hole transporting layer, the first carrier injecting layer 1800 is the electron injecting layer, and the second carrier injecting layer 1900 is the electron-hole injecting layer, and vice versa. However, in other embodiments, the light emitting element structure 1000 may still have the emission function without the first carrier injecting layer 1800 and the second carrier injecting layer 1900. Thus, the invention is not limited to the necessity of the first carrier injecting layer 1800 and the second carrier injecting layer 1900.

Furthermore, the first carrier transporting layer 1500 includes two first carrier transporting sub-layers 1520 that are stacked with each other. In addition, the transmission electrode layer 1700 is located between the two first carrier transporting sub-layers 1520. Here, the transmission electrode layer 1700 is used for allowing the carriers to pass through and conduct. Therefore, a first current outputted by the driving circuit layer 1100 is transmitted via the first electrode layer 1200 and the transmission electrode layer 1700 and inputted to the stack of the two first carrier transporting sub-layers 1520 with the transmission electrode layer 1700 so as to generate a second current flowing through the active layer 1400. The second current may be larger than the first current.

In other words, the component layout in which the transmission electrode layer 1700 is inserted between the two first carrier transporting sub-layers 1520 may transfer the first current applied to the transmission electrode layer 1700 and the first electrode layer 1200 so as to output the second current to the active layer 1400. The second current is different from the first current. By this way, when the second current is larger than the first current, the first current outputted by the driving circuit layer 1100 may be lower than the second current needed for driving the active layer 1400 so that the loading of the circuit components, e.g. transistors, can be reduced, and the reliability of the same can be enhanced.

To emit light from the active layer 1400, the transmission electrode layer 1700 may selectively be a transparent transmission electrode layer. However, if the transmission electrode layer 1700 is located at a position without shielding the active layer 1400, the transmission electrode layer 1700 is not required to have a light transparent feature. In particular, a material of the transmission electrode layer 1700 includes a metal, a metal oxide, a graphite carbon or a carbon nano-tube.

The transmission electrode layer 1700 may have a multi-hole structure for the carriers to pass through and conduct by certain processing procedures. For example, when manufacturing the transmission electrode layer 1700, the electrode layer may be formed by depositing a blended material made of volatile impurities and a metal material. Then, the transmission electrode layer 1700 is manufactured by heating or other methods to volatilize the impurities. Meanwhile, by controlling the manufacturing conditions, a hole of the transmission electrode layer 1700 can have a sub-micron diameter. Certainly, the aforementioned impurities may exist in the transmission electrode layer 1700 without being volatilized. In addition, the multi-hole structure of the transmission electrode layer 1700 may be implemented by an etching process. Thus, the hole of the transmission electrode layer 1700 may have different diameters according to different manufacturing procedures. The content as described above is only for descriptive purpose, and the invention is not limited thereto.

In detail, the light emitting element structure 1000 may be designed in top emission type, bottom emission type or double side emission type. As for the top emission type of design, a light from the active layer 1400 is emitted away from the substrate 1010, and thus, the components, i.e. the second electrode layer 1300, the second carrier injecting layer 1900 and the second carrier transporting layer 1600, located at a side of the active layer 1400 that is away from the substrate 1010 are required to have the light transmittance feature or to be transparent. Accordingly, the second electrode layer 1300 is required to be made of a transparent and conductive material, and the first electrode layer 1200 and the transmission electrode layer 1700 may selectively be a transparent or light-shielding electrode layer.

As for the bottom emission type of design, a light from the active layer 1400 is emitted toward the substrate 1010, and thus, the components, i.e. the first electrode layer 1200, the first carrier transporting layer 1500 and the first carrier injecting layer 1800 located at a side of the active layer 1400 that is adjacent to the substrate 1010 are required to have the light transmittance feature or to be transparent. In other words, the first electrode layer 1200 and the transmission electrode layer 1700 are required to be made of a transparent and conductive material, and the second electrode layer 1300 may selectively be a transparent or light-shielding electrode layer. As for the double side emission type of design, all the components are preferably made of a transparent material. Specially, the first electrode layer 1200, the first carrier injecting layer 1800, the first carrier transporting layer 1500, the transmission electrode layer 1700, the second carrier transporting layer 1600, the second carrier injecting layer 1900 and the second electrode layer 1300 are required to be made of a transparent material.

FIG. 1B is a schematic cross-sectional view of a light emitting element structure according to an embodiment of the invention. Referring to FIG. 1B, a light emitting element structure 2000 is disposed on a substrate 2010. Each component of the light emitting element structure 2000 is identical to the same of the afore-described light emitting element structure 1000. However, the components of the present embodiment are stacked in another manner. In particular, the components of the light emitting element structure 2000 are stacked in turn by the driving circuit layer 1100, the second electrode layer 1300, the second carrier injecting layer 1900, the second carrier transporting layer 1600, the active layer 1400, the first carrier transporting sub-layer 1520, the transmission electrode layer 1700, the first carrier transporting sub-layer 1520, the first carrier injecting layer 1800 and the first electrode layer 1200. In other words, the first electrode layer 1200 is located at a side of the active layer 1400 that is away from the substrate 2010, and the second electrode layer 1300 is located at another side of the active layer 1400 that is adjacent to the substrate 1010.

In particular, though the components of the light emitting element structure 2000 of the present embodiment are not stacked in the same order as illustrated in FIG. 1A, the function and the material of each component may be referred to the description as above. Accordingly, the light emitting element structure 2000 may employ a smaller current (or a lower bias voltage) for driving so that the reliability of each circuit component on the driving circuit layer 1100 can be maintained.

In detail, the circuit of the light emitting elements as described above can be implemented via various methods, and several examples will be provided hereinafter for explaining. However, it should be noted that the following embodiments are used for describing the spirit and the implementable methods of the invention, but do not intend to limit the invention.

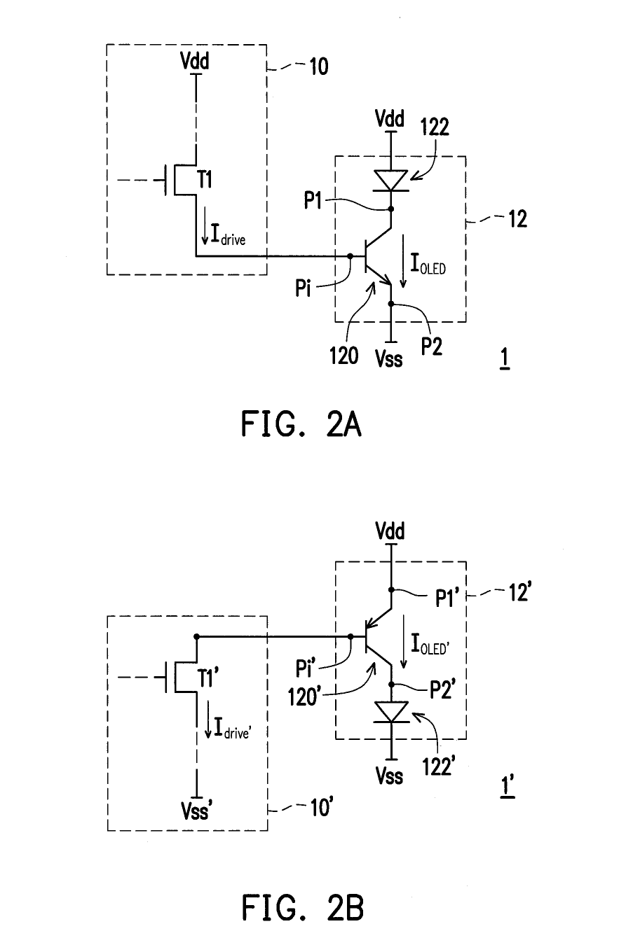

FIG. 2A is a schematic view of a light emitting element circuit 1 according to an exemplary embodiment of the invention. The light emitting element circuit 1 includes a driving unit 10 and a light emitting element 12. The driving unit 10 includes a driving transistor T1, which is connected between a system potential Vdd and the light emitting element 12 so as to provide a driving current Idrive to the light emitting element 12 at a light emission period. The layout of the driving unit 10 is, for example, like that of the driving circuit layer as illustrated in FIG. 1A and FIG. 1B. In addition, the layout of the light emitting element 12 in a substantial structure may be referred to the embodiment as illustrated in FIG. 1A, which is stacked in turn by the first electrode layer 1200, the first carrier injecting layer 1800, the first carrier transporting layer 1500, the transmission electrode layer 1700, the active layer 1400, the second carrier transporting layer 1600, the second carrier injecting layer 1900 and the second electrode layer 1300, or the embodiment as illustrated in FIG. 1B, which is stacked in turn by the second electrode layer 1300, the second carrier injecting layer 1900, the second carrier transporting layer 1600, the active layer 1400, the first carrier transporting sub-layer 1520, the transmission electrode layer 1700, the first carrier transporting sub-layer 1520, the first carrier injecting layer 1800, and the first electrode layer 1200.

In the present exemplary embodiment, the light emitting element 12 includes a current transferring unit 120 and a light emitting unit 122. Particularly, the current transferring unit 120 may be implemented by the stack of the first carrier transporting layer 1520, the transmission electrode layer 1700 and the first carrier transporting layer 1520, as illustrated in FIG. 1A and FIG. 1B. Meanwhile, the light emitting unit 122 may also be implemented by the stack of the first carrier injecting layer 1800, the first carrier transporting layer 1520, the active layer 1400, the second carrier transporting layer 1600 and the second carrier injecting layer 1900, as illustrated in FIG. 1A and FIG. 1B.

As illustrated in FIG. 2A, for descriptive convenience, the current transferring unit 120 and the light emitting unit 122 may be equivalent to structures of a bipolar junction transistor-like (BJT-like) and a organic light emitting diode (OLED) respectively, but the invention is not limited thereto. Structures that can achieve the current transferring and light emitting effect fall within the scope of the invention. For example, the light emitting unit 122 may be an electro-luminescence element, e.g. an inorganic LED structure. In the present embodiment, an element property of the current transferring unit 120 depends on the transmission property of the two first carrier transporting sub-layers 1520. When the first carrier transporting sub-layers 1520 are electron-hole layers, the element property of current transferring unit 120 is equivalent to a PNP-like type BJT, as illustrated in FIG. 2A.

The current transferring unit 120 is substantially a tri-terminal element, and the three terminals are a current input terminal Pi, a first terminal P1 and a second terminal P2. The current input terminal Pi is connected with a terminal of the driving transistor T1. At a light emission period, the current input terminal Pi may be used for receiving the driving current Idrive generated by the driving transistor T1. For example, referring to FIG. 2A, if the driving transistor T1 is a N-type transistor, the current input terminal Pi is connected with a source of the driving transistor T1, but the invention is not limited thereto. The first terminal P1 is coupled to the system potential Vdd. The light emitting unit 122 is equivalently connected between the first terminal P1 and to the system potential Vdd. The second terminal P2 is connected with a reference potential Vss, for example, a grounded potential. In addition, in other embodiments, the light emitting unit 122 may be equivalently connected between the first terminal P1 and another system potential Vcc (not shown). Thereby, the system potential connected with the first terminal P1 may selectively be identical to or different from the system potential connected with the driving transistor T1. Through the above-mentioned connection, the light emitting element 12 may transfer the driving current Idrive to a light-emitting current IOLED by the current transferring unit 120 so that the light-emitting current IOLED flows through the light emitting unit 122. Here, the value of the light-emitting current IOLED is larger than that of the driving current Idrive. It should be noted that the current input terminal Pi, the first terminal P1 and the second terminal P2 may be respectively considered as the transmission electrode layer 1700 and the two first carrier transporting sub-layers 1520 in the structure as illustrated in FIG. 1A and FIG. 1B.

In other words, if the current transferring unit 120 has a 100× magnification, and the light emitting unit 122 requires the light-emitting current of 1 micro-Ampere (uA) to achieve a default brightness value, the driving current Idrive only needs to be provided with 10 nano-Ampere (nA) to achieve the afore-described effect. By this way, the invention can significantly reduce the current supply of the driving unit 10. Correspondingly, the invention can mitigate the stress effect endured by the driving transistor T1 so as to postpone the lifespan of the elements and reduce the area of the driving transistor T1. Thereby, the flexibility and abundance of the circuit layout can be enhanced.

FIG. 2B is a schematic view of a light emitting circuit 1′ according to an exemplary embodiment of the invention. Referring to FIG. 2B, another implementation aspect of a light emitting unit 12′ of the invention is disclosed. The light emitting unit 12′ includes a current transferring unit 120′ and a light emitting unit 122′. The current transferring unit 120′ has a current input terminal Pi′, a first terminal P1′ and a second terminal P2′. The current input terminal Pi′ is connected with a terminal of a driving transistor T1′ of a driving unit 10′ so that a driving current Idrive′ generated by the driving transistor T1′ is received at a light emission period. The driving current Idrive′ flows in a reverse direction of the driving current Idrive generated by the driving unit 10, as illustrated in FIG. 2A. The first terminal P1′ is coupled to a system potential Vdd. The light emitting unit 122′ is equivalently connected between the second terminal P2′ and a reference potential Vss. A light-emitting current IOLED′ applied to the light emitting unit 122′ for light emitting is operated by the current transferring unit 120′ so as to be larger than the value of the Idrive′. Here, the first carrier transporting sub-layers 1520 to form the transferring unit 122′ are, for example, electron layers, and thus, the element property of the current transferring unit 120′ is equivalent to the NPN-like type BJT.

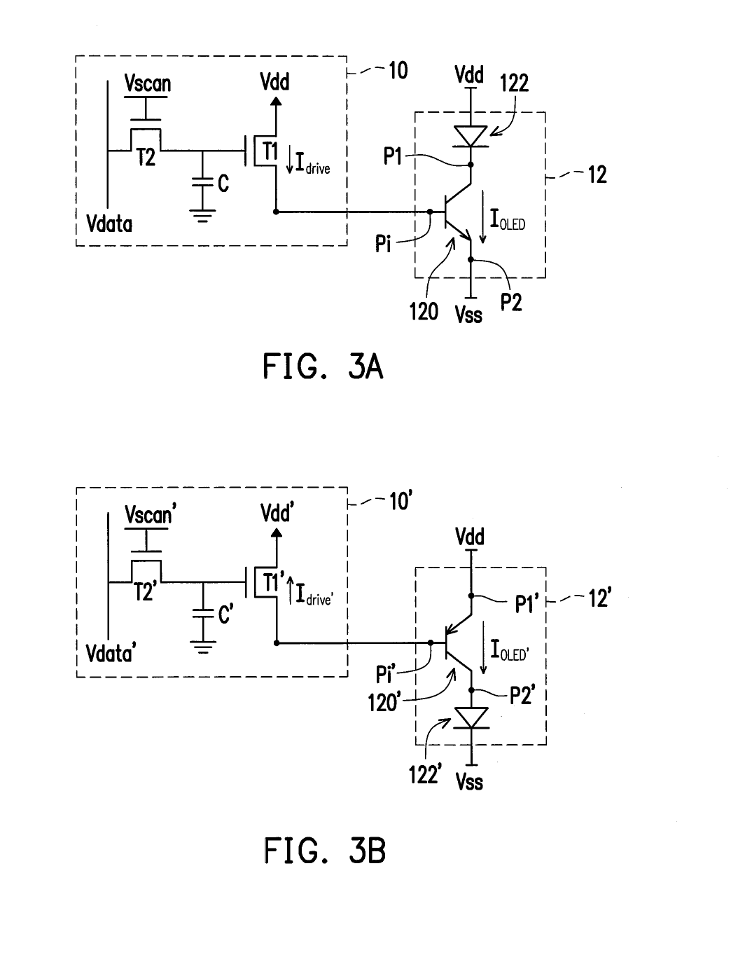

FIG. 3A is a schematic view illustrating another method for implementing the light emitting element circuit depicted in FIG. 2A. Referring to FIG. 2A with FIG. 3A, the driving unit 10 according to the exemplary embodiment includes two transistors T1 and T2 and a storage capacitor C, i.e. a 2T1C circuit design as shown in the circuit diagram. The driving unit 10 is operated at two periods, one is a data voltage writing period, and the other is an electro-enabled period. The electro-enabled period may also be called as the light emission period. At the data voltage writing period, the transistor T2 receives a scan signal Vscan (now in a high voltage level) and is therefore turned on so that a data voltage Vdata is written into the storage capacitor C. Then, at the electro-enabled period, the transistor T2 is turned off by the scan signal Vscan (now in a low voltage level). The transistor T1 is turned on by the data voltage Vdata to generate the driving current Idrive and further inputs the driving current Idrive to the current input terminal Pi of the current transferring unit 120. The circuit operation and the effect to be achieved of the current transferring unit 120 are similar to those as illustrated in FIG. 2A, and will not be described repeatedly hereinafter.

FIG. 3B is a schematic view illustrating another method for implementing the light emitting element circuit depicted in FIG. 2B. Referring to FIG. 2B with FIG. 3B, the driving unit 10′ according to the exemplary embodiment includes two transistors T1′ and T2′ and a storage capacitor C′, i.e. a 2T1C circuit design as shown in the circuit diagram. Here, the connection between the driving unit 10′ and the light emitting unit 12′ and the operation thereof are similar to those illustrated in FIG. 2B and thus, will not be described repeatedly hereinafter.

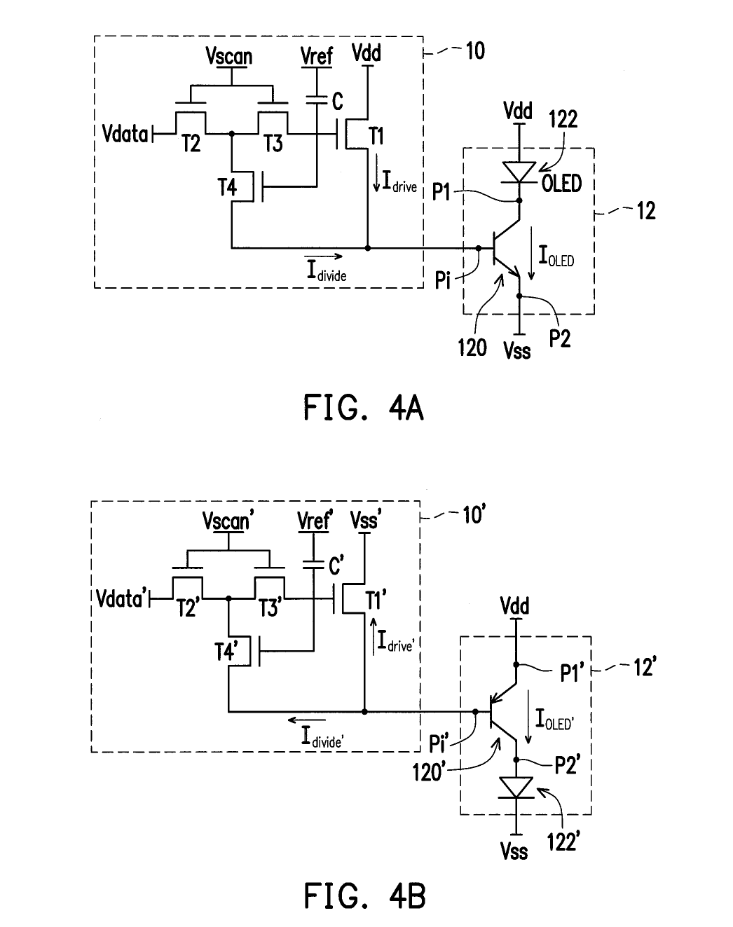

FIG. 4A is a schematic view illustrating an alternative method for implementing the light emitting element circuit depicted in FIG. 2A. Referring to FIG. 2A with FIG. 4A, the driving unit 10 according to the exemplary embodiment includes four transistors T1 through T4 and a storage capacitor C, i.e. a 4T1C circuit design as shown in the circuit diagram. The 4T1C circuit differs from the 2T1C circuit in that another pair of the transistors, T3 and T4, forming a diode connection configuration is connected between the transistors T1 and T2. The driving unit 10 is operated at two periods, one is a data voltage writing period, and the other is an electro-enabled period, which may also be called as a light-emitting period. At the data voltage writing period, the transistors T2 and T3 are turned on by a scan signal Vscan (now in a high voltage level), wherein the transistors T3 and T4 are connected with each other to form a connection configuration as a diode. At this time, a loop from the data voltage Vdata to the reference potential Vss is formed and a voltage-divided current Idivide sequentially flowing through the transistors T2 and T4, the current input terminal Pi and the second terminal P2 of the current transferring unit 120 is generated. Thereby, a divided voltage (VP) is established on a node of the transistor T2 connecting with the transistor T4. Here, a circuit system (not shown) controls the reference potential Vref as a zero-voltage level so that a capacitor voltage stored in the capacitor C is substantially the divided voltage (VP). Meanwhile, the driving transistor T1 is also driven and turned on by the divided voltage (VP) and the driving current Idrive flowing through the transistors T1, the current input terminal P1 and the second terminal P2 of the current transferring unit 120 is generated so as to form another loop. In the present embodiment, the transistors T3 and T4 form a diode connection configuration connected with the transistor T1 in parallel. Thus, a cross-voltage on the transistor T4, which is defined as a compensation voltage VC, is equal to a threshold voltage Vth of the transistor T1. Further, the divided voltage (VP) is substantially equal to the compensation voltage (VC) plus the cross-voltage (VF) of the current transferring unit 120, i.e. the cross-voltage formed between the current input terminal P1 and the second terminal P2.

Afterward, referring to FIG. 4A, during the electro-enabled period, the transistors T2 and T3 are turned-off by the scan signal Vscan (now in the low potential). Here, the circuit system (not shown) controls the reference potential Vref as the zero-voltage level, and the divided voltage (VP) continuously controls the transistor T1 as turned on so as to input the driving current Idrive to flow into the current input terminal Pi of the current transferring unit 120, of which the operation and the effect to be achieved is similar to those illustrated in FIG. 2A, and will not be described repeatedly hereinafter. At this period, the voltage-divided current no longer flows. Moreover, in an embodiment, at the electro-enabled period, the storage capacitor C controls the transistor T1 as in an enable and a disable states alternatively based on the reference potential Vref with the zero voltage level or negative voltage level.

When the transistor T1 and the current transferring unit 120 are changed in the element characteristics due to being operated for a long time, the diode connection configuration of the transistors T3 and T4 facilitates to compensate the change. For example, an impedance value of the transistor T1 and the current transferring unit 120 may get higher due to being operated for a long time, which results in an increase of the threshold voltage (Vth and VF) of the transistor T1. The diode connection configuration of the transistors T3 and T4 may function in response to a change volume of threshold voltage Vth of the transistor T1 at the data voltage writing period. Particularly, the value of the compensation voltage (VC) is adjusted based on the change volume so as to change the value of the divided voltage (VP). Thereby, at the electro-enable period, the storage capacitor C can control the value of the driving current Idrive flowing through the transistor T1. In addition, when the cross-voltage (VF) of the current transferring unit 120 is changed, the diode connection configuration of the transistors T3 and T4 can function in response to the change of the cross-voltage (VF) so as to compensate the value of the driving current Idrive. Hence, by the operation of the 4T1C circuit, the driving current Idrive may be controlled to flow stably without being affected by a current decrease resulted from the variation of the transistor T1 and the current transferring unit 120 being operated for a long time.

FIG. 4B is a schematic view illustrating another method for implementing the light emitting element circuit depicted in FIG. 2B. Referring to FIG. 2B with FIG. 4B, the driving unit 10′ according to the present exemplary embodiment includes four transistors T1 through T4 and a capacitor C, i.e. a 4T1C circuit diagram. Here, the connection between the driving unit 10′ and the light emitting unit 12′ and the current operation thereof are similar to those illustrated in FIG. 2B, and will not be described repeatedly hereinafter.

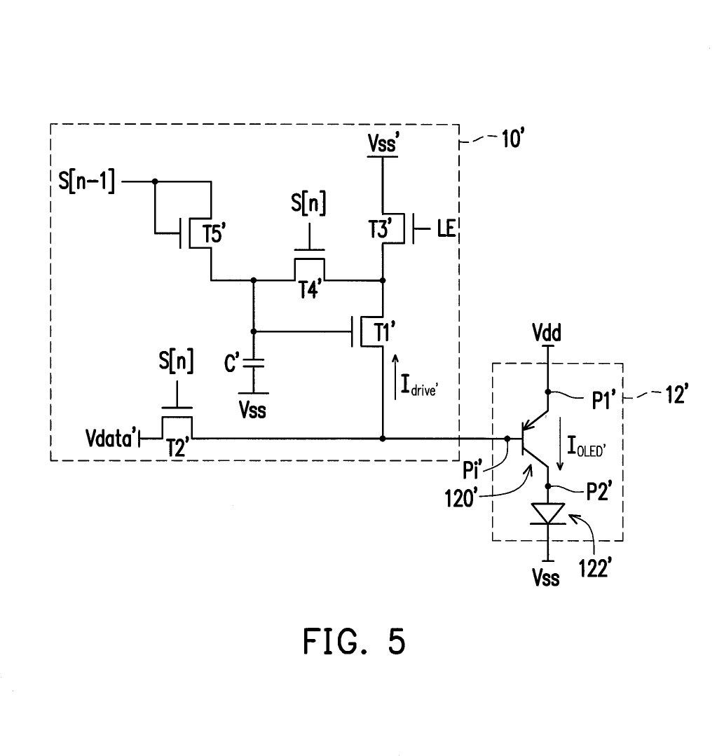

FIG. 5 is a schematic view illustrating still another method for implementing the light emitting element circuit of the invention. Referring to FIG. 2B with FIG. 5, the driving unit 10′ according to the present exemplary embodiment includes five transistors T1′ through T5′ and a capacitor C′, i.e. a 5T1C circuit diagram. The 5T1C circuit is different from the 2T1C circuit in that 5T1C circuit has more transistors than the 2T1C circuit, i.e. T3′ through T5′. The transistor T3′ is connected between the system potential Vss' and the transistor T1′ and controlled by a luminescence-enabled signal LE. The transistor T4′ and the transistor T1′ are connected with each other to form a diode connection configuration. The transistor T5′ is connected with the capacitor C′ for initiating a voltage status of the capacitor C′ before a data voltage is written into the storage capacitor C′. A stress of the transistor T1′ can be compensated by the 5T1C circuit of the present exemplary embodiment so as to, when the 5T1C circuit is operated, avoid the problem that the light emitting element 12′ emits light in response to the data voltage Vdata, by which a contrast ratio for displaying is further enhanced.

During the process of operating the 5T1C circuit, the resetting period is initially entered, then the data voltage writing period and the electro-enabled period. At the resetting period, only a resetting scan signal S[n−1] is enabled, and therefore, a gate voltage of the transistor T1′ is equal to VH−Vth(T5′) in response to the transistor T5′ being turned-on. Here, Vth(T5′) is a threshold voltage of the transistor T5′, and VH is a highest voltage level of the resetting scan signal S[n−1]. At the same time, in response to the luminescence-enabled signal LE being disabled, the transistor T3′ is in a turned-off status so as to avoid the driving current Idrive from flowing through the transistor T1′ so that an image contrast is maintained.

Thereafter, at the data voltage writing period, since only a write-in signal S[n] is enabled, the transistor T2′ and the transistor T4′ are simultaneously stayed in a turned-on status. Under such condition, the data voltage Vdata is transported to the storage capacitor C′ via the transistor T2′ and the transistor T1′ in a diode-connected configuration, by which the gate voltage of the transistor T1′ is equal to Vdata′+Vth(T1′). Vth(T1′) is the threshold voltage of the transistor T1′.

Meanwhile, in response to the disable of the resetting scan signal S[n−1] and the luminescence-enabled signal LE, both the transistor T5′ and the transistor T3′ are in the turned-off status. Additionally, the voltage level of the reference potential Vss' is substantially not smaller than the highest voltage level of the data voltage Vdata′ minus a turned-on voltage Voled_th of the light emitting unit 122′, i.e. Vss′≧Vdata′−Voled_th. Thereby, a malfunction of sudden luminance does not happen to the light emitting unit 122′ at the data voltage writing in period.

At last, at the electro-luminescence period, since only the luminescence-enabled signal LE is enabled, the transistor T2′, transistor T4′ and the transistor T5 are in the turned-off status while the transistor T1′ and the transistor T3′ are in the turned-on status. At the meantime, in response to the system potential Vdd staying in the high voltage level (VH), a flow of the driving current Idrive is generated in the transistor T1′.

Since a Vdata′+Cth(T1′) voltage level is recorded in a terminal of the storage capacitor C′ at the data voltage writing period, the driving current Idrive is not influenced by the change of the threshold voltage of the transistor T1′ at the later electro-enabled period. Here, the connection between the driving unit 10′ and the light emitting unit 12′ of the 5T1C circuit and the current operation thereof are similar to those illustrated in FIG. 2B, and will not be described repeatedly hereinafter.

In view of the foregoing, the invention inserts a layer of electrode into the carrier transporting layers of the same carrier so as to form the structure stacked by the carrier transporting layer, the electrode layer, and the carrier transporting layer. When a current flows into an interface of the electrode layer in such a stack structure, a larger current is generated in another side of the electrode layer. That is to say, such stack structure is equivalent to a current converter, and even further similar to a BJT-like function which is operated to amplify the current. Thus, the light emitting element according to the embodiments of the invention can be considered as a built-in current transferring unit which can be driven by a smaller current from the external. Accordingly, the burden of the circuit is mitigated, and provided with better reliability. Although the invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed descriptions.

What is claimed is:

1. A light emitting element structure disposed on a substrate, and the light emitting element structure comprising:
a driving circuit layer disposed on the substrate;
a first electrode layer connected with the driving circuit layer;
a second electrode layer connected with the driving circuit layer;
an active layer located between the first electrode layer and the second electrode layer;
a first carrier transporting layer located between the first electrode layer and the active layer, and the first carrier transporting layer consisting of two first carrier transporting sub-layers stacked with each other;
a second carrier transporting layer located between the second electrode layer and the active layer; and
a transmission electrode layer connected with the driving circuit layer and located between the two first carrier transporting sub-layers.

2. The light emitting element structure according to claim 1, wherein a first current output by the driving circuit layer is input to a stack of the two first carrier transporting sub-layers and the transmission electrode layer via the first electrode layer and the transmission electrode layer so as to generate a second current flowing through the active layer, and the second current is different from the first current.

3. The light emitting element structure according to claim 1, wherein the first carrier transporting layer and the second carrier transporting layer respectively transports different carriers comprising electrons and electron-holes.

4. The light emitting element structure according to claim 1, wherein a material of the transmission electrode layer comprises metal, metal oxide, graphite carbon or carbon nano-tube.

5. The light emitting element structure according to claim 1, wherein the transmission electrode layer has a plurality of holes, and the plurality of holes has a sub-micron diameter.

6. The light emitting element structure according to claim 1, wherein the transmission electrode layer is a transparent transmission electrode layer.

7. The light emitting element structure according to claim 1, wherein the first electrode layer is located at a side of the active layer that is adjacent to the substrate, and the second electrode layer is located at another side of the active layer that is away from the substrate.

8. The light emitting element structure according to claim 1, wherein the first electrode layer is located at a side of the active layer that is away from the substrate, and the second electrode layer is located at another side of the active layer that is adjacent to the substrate.

9. The light emitting element structure according to claim 1, further comprising a first carrier injecting layer located between the first carrier transporting layer and the first electrode layer.

10. The light emitting element structure according to claim 1, further comprising a second carrier injecting layer located between the second carrier transporting layer and the second electrode layer.

11. The light emitting element structure according to claim 1, wherein a material of the active layer is a light emitting material.

12. The light emitting element structure according to claim 1, wherein at least one of the first electrode layer and the second electrode layer is a light-transmission electrode layer.

13. A light-emitting device circuit, comprising:
a driving unit used for generating a driving current at a light emission period; and
a light emitting element, comprising:
a current transferring unit connected with the driving unit to receive the driving current so as to generate a light emitting current; and
a light emitting unit connected with the current transferring unit, and the light emitting unit emitting light in response to the light emitting current at the light emission period.

14. The light-emitting device circuit according to claim 13, wherein the light emitting current flowing through the light emitting unit is functioned by the current transferring unit so that a value of the light emitting current is larger than that of the driving current.

15. The light emitting element circuit according to claim 13, wherein the light emitting unit comprises a stack comprising in turn of a first electrode layer, two first carrier transporting sub-layers, a light emitting layer, a second carrier transporting layer and a second electrode layer.

16. The light emitting element circuit according to claim 15, wherein a transmission electrode layer is further disposed between the two first carrier transporting layers to form the current transferring unit.

17. The light emitting element circuit according to claim 16, wherein the transmission electrode layer of the current transferring unit, the two first carrier transporting sub-layers are respectively connected with the driving unit, a system potential and a reference potential.

18. The light emitting element circuit according to claim 17, wherein the light emitting unit is connected between the circuit transferring unit and the system potential.

19. The light emitting element circuit according to claim 17, wherein the light emitting unit is connected between the circuit transferring unit and the reference potential.

20. The light emitting element circuit according to claim 13, wherein the current transferring unit and the driving unit are coupled to a same system potential.

21. The light emitting element circuit according to claim 13, wherein the current transferring unit is coupled to a system potential, and the driving unit is coupled to another system potential.

22. The light emitting element circuit according to claim 13, wherein the driving consists of at least one transistor and at least one capacitor.
